(19) United States
(12) Patent Application Publication
(10) Pub. No.: US 2016/0240373 A1
(43) Pub. Date: Aug. 18, 2016

(54) METHOD FOR FORMING OXIDE LAYER BY OXIDIZING SEMICONDUCTOR SUBSTRATE WITH HYDROGEN PEROXIDE

(71) Applicant: ASM IP Holding B.V., Almere (NL)

(72) Inventors: Fu Tang, Gilbert, AZ (US); Michael Givens, Scottsdale, AZ (US); Qi Xie, Leuven (BE); Jan Willem Maes, Wilrijk (BE); Bert Jongbloed, Oud-Heverlee (BE); Radko G. Bankras, Almere (NL); Theodorus G.M. Oosterlaken, Oudewater (NL); Dieter Pierreux, Dilbeek (BE); Werner Knaepen, Leuven (BE); Harald B. Profijt, Leuven (BE); Cornelius A. van der Jeugd, Heverlee (BE)

(21) Appl. No.: 14/621,174

(22) Filed: Feb. 12, 2015

(51) Int. Cl. H01L 21/02

(52) U.S. Cl. CPC H01L 21/02236; H01L 21/02175; H01L 21/02255; H01L 21/02238; H01L 21/02241

(57) ABSTRACT

In some embodiments, an oxide layer is grown on a semiconductor substrate by oxidizing the semiconductor substrate by exposure to hydrogen peroxide at a process temperature of about 500° C. or less. The exposure to the hydrogen peroxide may continue until the oxide layer grows by a thickness of about 1 Å or more. Where the substrate is a germanium substrate, while oxidation using H₂O has been found to form germanium oxide with densities of about 4.25 g/cm³, oxidation according to some embodiments can form an oxide layer with a density of about 6 g/cm³ or more (for example, about 6.27 g/cm³). In some embodiments, another layer of material is deposited directly on the oxide layer. For example, a dielectric layer may be deposited directly on the oxide layer.

### BACKGROUND

1. Field

This disclosure relates to semiconductor processing and, more particularly, to forming oxide layers by oxidation with hydrogen peroxide.

2. Description of the Related Art

As the dimensions of semiconductor devices in integrated circuits become ever smaller, the requirements for materials forming the integrated circuits are evolving. Oxide layers are commonly formed during integrated circuit fabrication and the requirements for the composition, stability, and electrical properties of these layers are changing with the dimensions of the integrated circuits in which they are present. Consequently, there is a continuing need for methods for forming high quality oxide layers.

### SUMMARY

In one aspect, a method is provided for semiconductor processing. The method includes growing an oxide layer on a semiconductor substrate, the oxide layer growing by a thickness of about 1 Å or more. Growing the oxide layer includes oxidizing the semiconductor substrate by exposing the semiconductor substrate to hydrogen peroxide at a process temperature of about 500° C. or less.

According to another aspect, a method is provided for semiconductor processing. The method comprises forming an oxide layer by exposing a semiconductor substrate to hydrogen peroxide. The process temperature for exposing the semiconductor substrate is about 500° C. or less while forming the oxide layer. Another layer of material is then deposited directly on the oxide layer.

### BRIEF DESCRIPTION OF THE DRAWINGS

FIG. 1 is a flow chart generally illustrating a process for forming an oxide layer, according to some embodiments.

FIG. 2 shows a plot of the increase in the thickness of oxide layers as a function of oxidation temperature for oxidations of germanium substrates in steam and hydrogen peroxide, according to some embodiments.

FIG. 3 shows a plot of the increase in mass of germanium substrates as a function of the increases in the thicknesses of the oxide layers formed by the oxidations of FIG. 2.

FIG. 4 shows a plot of the increase in the thickness of oxide layers as a function of oxidation temperature for oxidations of monocrystalline silicon substrates in steam and hydrogen peroxide, according to some embodiments.

FIG. 5 shows a plot of the increase in the thickness of oxide layers as a function of oxidation temperature for oxidations of amorphous silicon substrates in steam and hydrogen peroxide, according to some embodiments.

FIG. 6 shows a plot of the increase in mass of monocrystalline and amorphous silicon substrates as a function of the thicknesses of the oxide layers formed by the oxidations of FIGS. 4 and 5.

### DETAILED DESCRIPTION

Integrated circuits are typically fabricated using semiconductor substrates. These substrates may be subjected to various processes to modify the conductivity of the semiconductor or semiconductors that form the substrates, thereby allowing the fabrication of a range of electrical devices, which then constitute parts of the integrated circuits. For example, doping may be used to increase the conductivity of semiconductors, while processes such as oxidation may be used to form, for example, a dielectric material from the semiconductors.

Semiconductor substrates have traditionally been formed of silicon. More recently, semiconductor substrates containing germanium have been investigated as alternatives to silicon substrates. The germanium-containing substrates can have a higher electrical carrier mobility, which may be desirable in some applications, such as for forming transistors.

As noted above, processes that form an oxide material from the semiconductor are needed for integrated circuit fabrication. As also indicated above, one approach for forming such an oxide material is to expose the semiconductor to an oxidant to oxidize the semiconductor, and thereby form a semiconductor oxide. It has been found, however, that oxidizing germanium-containing substrates to form stable and high quality oxides can be challenging. Common oxidants, such as H₂O, have been found to form oxides that have low thermal stability and low quality. For example, oxidation using H₂O has been found to form relatively low density oxides. Without being limited by theory, this low density is believed to be associated with poor dielectric properties, thereby making a higher density oxide desirable. In addition, H₂O has been found to both oxidize the semiconductor and undesirably etch the resulting semiconductor oxide.

Surprisingly, in accordance with embodiments disclosed herein, it has been found that low temperature oxidation processes using hydrogen peroxide (H₂O₂) can form a denser and higher quality oxide than traditional oxidation processes, such as those using H₂O. In some embodiments, an oxide layer is formed on a semiconductor substrate by oxidizing the semiconductor substrate by exposure to hydrogen peroxide at a process temperature of about 500° C. or less. For example, the process temperature may be about 400° C. or less, about 300° C. or less, or about 250° C. or less, including being in the range of about 500° C. to about 175° C., about 400° C. to about 175° C., about 400° C. to about 200° C., or about 300° C. to about 200° C. In some embodiments, the exposure to the hydrogen peroxide may continue until the thickness of the oxide layer grows by about 1 Å or more. In some embodiments, another layer of material is deposited directly on the oxide layer. For example, a dielectric layer may be deposited directly on the oxide layer, such that the dielectric layer is in contact with the oxide layer.

Advantageously, while oxidation using H₂O has been found to form germanium oxide with densities of less than about 5 g/cm³ (for example, about 4.25 g/cm³), oxidation with hydrogen peroxide at temperatures disclosed herein has been found to form a relatively high density oxide layer with a density of about 6 g/cm³ or more (for example, about 6.27 g/cm³). Without being limited by theory, such high densities are believed to provide superior dielectric properties, relative to a lower density oxide.

It will be appreciated that oxidation using hydrogen peroxide has been proposed in Japanese patent publications JP 3392789 and JP 2001-230246. Among other things, both references teach oxidations at temperatures of 800° C., and JP 3392789 also teaches oxidation at 700° C. with irradiation using UV light, which provides additional energy. It has been found, however, that such oxidations can produce poor process results. Without being limited by theory, it is believed that the disclosed temperatures contribute to the poor results. For example, while oxidizing germanium at such temperatures can form germanium oxide, exposing the resulting germanium oxide to these temperatures can cause the germanium oxide to evaporate, thereby partially removing the oxide. In addition, such temperatures have been found to undesirably decompose hydrogen peroxide. Advantageously, oxidation with hydrogen peroxide at the temperatures disclosed herein can significantly avoid such decomposition and evaporation, thereby providing higher quality oxide layers and higher growth rates.

While providing particular benefits for oxidizing germanium-containing substrates to form germanium oxide, it will appreciated that the methods disclosed herein may also be advantageously applied to oxidizing other semiconductors, including substrates containing silicon and/or group III-V semiconductors. For example, in some embodiments, silicon-containing substrates may be oxidized, thereby forming silicon oxide. In some embodiments, the substrates may contain more than one of the above-noted semiconductors (for example, silicon germanium substrates) or may contain only a single one of the semiconductors. In addition, while the oxide layers (for example, germanium oxide or silicon oxide) may be utilized as a dielectric layer, the oxide layers may also be used as a passivation layer or an interface layer.

Reference will now be made to the drawings.

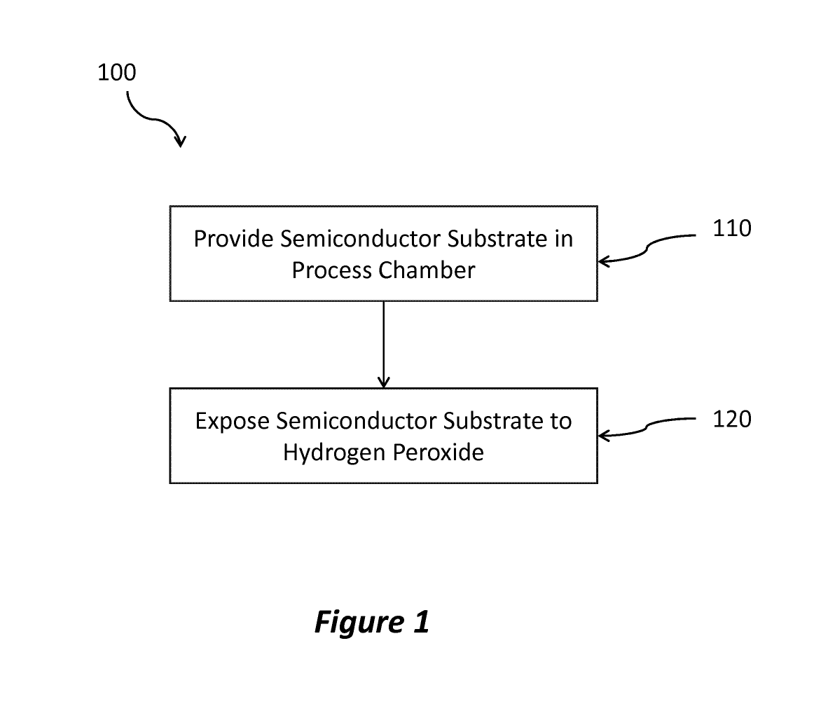

FIG. 1 is a flow chart generally illustrating a process 100 for forming an oxide layer. At block 110, a semiconductor substrate is provided in a process chamber. As used herein, it will be appreciated that a semiconductor substrate is a substrate that is at least partially formed of semiconductor material. For example, in some embodiments, the semiconductor substrate may be a semiconductor wafer, or may be a semiconductor wafer having overlying conductive and/or dielectric materials. The semiconductor may be silicon and/or germanium, such that the substrate maybe a silicon substrate, a germanium substrate, or a silicon-germanium substrate. In some embodiments, the substrate may contain a III-V semiconductor. The III-V semiconductor may contain Ga and As. In some embodiments, the substrate may be silicon substrate containing one or more of a germanium layer, a silicon germanium layer, and a III-V semiconductor layer.

In some embodiments, the process chamber may be a batch process chamber, which may accommodate 20 or more, 50 or more, or 100 or more semiconductor substrates. In some other embodiments, the process chamber may be a single substrate process chamber configured to accommodate only a single substrate at a time.

With continued reference to FIG. 1, at block 120, the semiconductor substrate is oxidized by exposure to hydrogen peroxide. The hydrogen peroxide may be delivered to the process chamber as a vapor and preferably substantially remains as hydrogen peroxide (rather than a decomposition product) between entering the process chamber and contacting the semiconductor substrate. In some embodiments, the semiconductor substrate is heated to a process temperature in the range of about 500° C. or less, including about 175 to about 500° C. In some embodiments, the process temperature may be about 400° C. or less, about 300° C. or less, or about 250° C. or less, including being in the range of about 500° C. to about 175° C., about 400° C. to about 175° C., about 400° C. to about 200° C., or about 300° C. to about 200° C. The oxidation preferably continues until an oxide layer having a thickness of about 1 Å or more, about 10 Å or more, or about 30 Å or more is formed. In some embodiments, oxidizing the semiconductor substrate is preferably a thermal oxidation in which energy for the oxidation is supplied by heat, without exposure to plasma or radicals generated by a plasma or radical generator.

It will be appreciated that the composition of the hydrogen peroxide-containing gas or vapor entering the process chamber may impact the oxidation, including the rate of growth and the quality of the resulting oxide. In some embodiments, the system for delivering hydrogen peroxide to the process chamber is configured to deliver a highly uniform amount of hydrogen peroxide to the process chamber over time.

An example of a suitable hydrogen peroxide delivery system is disclosed in U.S. Provisional Patent Application No. 61/972,005, filed Mar. 28, 2014, and entitled METHOD AND SYSTEM FOR DELIVERING HYDROGEN PEROXIDE TO A SEMICONDUCTOR PROCESSING CHAMBER (attorney docket no. ASMINT.124PRF). That delivery system includes a process canister for holding a H₂O₂/H₂O mixture in a liquid state, an evaporator provided with an evaporator heater, a first feed line for feeding the liquid H₂O₂/H₂O mixture to the evaporator, and a second feed line for feeding the evaporated H₂O₂/H₂O mixture to the processing chamber. The evaporator preferably evaporates the liquid mixture completely and the composition of the H₂O₂/H₂O mixture before and after evaporation is preferably essentially the same. The evaporator heater is configured to heat the evaporator to a temperature lower than 120° C., and the second feed line is provided with a heater configured to heat that feed line to a temperature equal to or higher than the temperature of the evaporator.

It will be appreciated that processing results using evaporation of an aqueous hydrogen peroxide solution held in a canister can be inconsistent because the vapor pressures and boiling points of H₂O₂ and H₂O are different, which can cause one of these chemical species to be evaporated at a preferential rate relative to the other species. This can substantially change the composition of the liquid H₂O₂/H₂O mixture over time, which can cause process results to vary between substrates processed at different times. According to some embodiments, a consistent concentration of H₂O₂ can be delivered to the process chamber by feeding a liquid H2O2/H2O mixture into an evaporator and evaporating the liquid completely. Decomposition of H2O2 in the evaporator can substantially be avoided by maintaining the evaporator at a temperature of about 120° C. to about 40° C., about 110° C. to about 50° C., about 100° C. to about 50° C., or about 80° C. to about 60° C. The vapor is then flowed into a process chamber, for example, with a carrier gas, such as an inert carrier gas. In some embodiments, the exposure to H₂O₂ can include a simultaneous exposure to H₂O due to both H₂O₂ and H₂O being present in the hydrogen peroxide vapor.

With continued reference to FIG. 1, the semiconductor substrate may have a surface oxide before being oxidized. Such a surface oxide may be, for example, a native oxide formed by reaction of the substrate surface with an oxidant in the ambient atmosphere. The native oxide may be formed at one or more times before exposure to the hydrogen peroxide, for example, during transport and/or loading into the process chamber. In some other embodiments, the substrate surface, or parts of the substrate surface, may include a semiconductor free of oxide before the oxidation using hydrogen peroxide. For example, any surface oxide may be removed before the oxidation.

When the substrate is a germanium substrate, a germanium oxide may be present in some embodiments before oxidizing the substrate at block 120. It will be appreciated that germanium oxide can exist in two forms, a relatively dense rutile form and a less dense hexagonal form. The surface oxide present before the oxidation of block 120 is believed to typically be in the less dense hexagonal form, having a density of about 5 g/cm³ or less (for example, about 4.25 g/cm³). With the oxidation of block 120, the hydrogen peroxide exposure is believed to promote the formation of germanium oxide existing in the desirably denser rutile form. Thus, the hydrogen peroxide may both increase the thickness of the surface oxide layer and also increase the density of that layer. In some embodiments, the density may be increased to a level of about 6 g/cm³ or more (for example, about 6.27 g/cm³).

After block 120, the semiconductor substrate may be subjected to further processing. For example, other materials (for example, conductive or dielectric materials) may be deposited directly on the oxide layer formed in block 120. In some embodiments, the oxide layer may be used as a dielectric layer, for example, to provide electrical isolation between conductive features, some of which may be formed directly on the oxide layer. In some embodiments, the hydrogen peroxide may passivate the substrate surface. Without being limited by theory, it is believed that delivering H₂O₂ to a substrate substantially without decomposition can advantageously provide two OH groups to the substrate surface (in comparison to, for example, the one OH group and one H of H₂O). For germanium-containing substrates, this can provide a surface with extensive Ge—O bonds, which are stronger than Ge—H bonds. These relatively strong bonds can enhance the thermal stability of the oxide layer by reducing the likelihood that the strongly bonded OH surface species would be displaced by another chemical species. In addition, it is believed that the OH groups may beneficially reduce trap states near the substrate surface. In some embodiments, alternatively or in addition to functioning as a dielectric and/or passivation layer, the oxide layer may simply be used as an interface layer between the semiconductor substrate and a deposited overlying material.

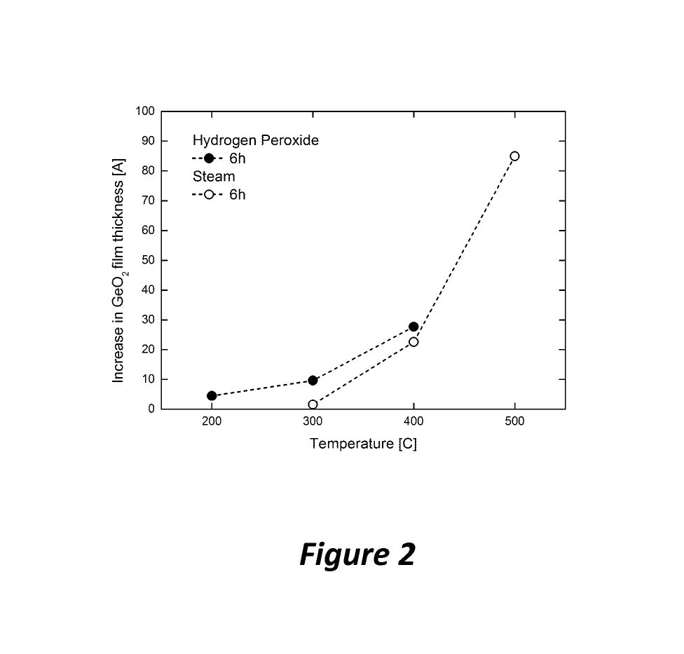

Reference will now be made to FIGS. 2-6, which document results from oxidation processes for forming oxide layers under varying conditions, as discussed below. The oxidation processes were performed in an A412™ vertical furnace available from ASM International N.V. of Almere, the Netherlands. The furnace has a process chamber that can accommodate a load of 150 semiconductor substrates having a diameter of 300 mm, with the substrates held in a wafer boat. Hydrogen peroxide was provided to the process chamber using a supply system described in U.S. Provisional Patent Application No. 61/972,005, as discussed herein.

The oxide layers were formed using, alternatively, hydrogen peroxide and steam (H₂O). For both types of processes, substrates were loaded into the process chamber with an atmosphere of nitrogen and oxygen gas. The steam oxidations were performed under a process chamber pressure of 750 Torr, with an oxygen gas partial pressure of 187 Torr and an H₂O partial pressure of 563 Torr. The process temperatures were varied from 300° C.-500° C. for different batches of substrates. Depending on the batch, the process temperature was 300° C., 400° C., or 500° C. The total oxidation time was 360 minutes (6 hours).

The hydrogen peroxide oxidations were performed under a process chamber pressure of 100 Torr, with a nitrogen gas partial pressure of 41 Torr, a H₂O partial pressure of 48 Torr, and a hydrogen peroxide partial pressure of 11 Torr. Process temperatures for different batches of substrates varied from 200° C. to 400° C., depending on the batch. In particular, process temperatures of 200° C., 300° C., or 400° C. were used. The total oxidation time was 360 minutes (6 hours).

As discussed further below, the oxidations were performed on batches of germanium substrates and silicon substrates (in the form of germanium films on silicon wafers and silicon wafers). A surface oxide was present on the substrates before the oxidations.

FIG. 2 shows a plot of the increase in the thickness of oxide layers as a function of oxidation temperature for oxidations of germanium substrates in steam and hydrogen peroxide. The Y-axis shows in angstroms the increase or growth in thickness of germanium oxide resulting from the oxidations. The X-axis shows in degrees Celsius the temperatures for the oxidations. As can be seen in the plot, the oxide layer thickness increased with increasing temperatures. For oxidations with hydrogen peroxide, low temperatures of about 200° C. were still found to provide useful oxide thicknesses, while steam caused little oxide growth even at 300° C. Also, the oxide growth rate was greater for hydrogen peroxide at every temperature for which hydrogen peroxide and steam were both tested. It will be appreciated that the effectiveness of hydrogen peroxide at growing oxide at such low temperatures can provide benefits for compatibility with a wide range of materials on the substrate, some of which may be sensitive to exposure to high temperatures.

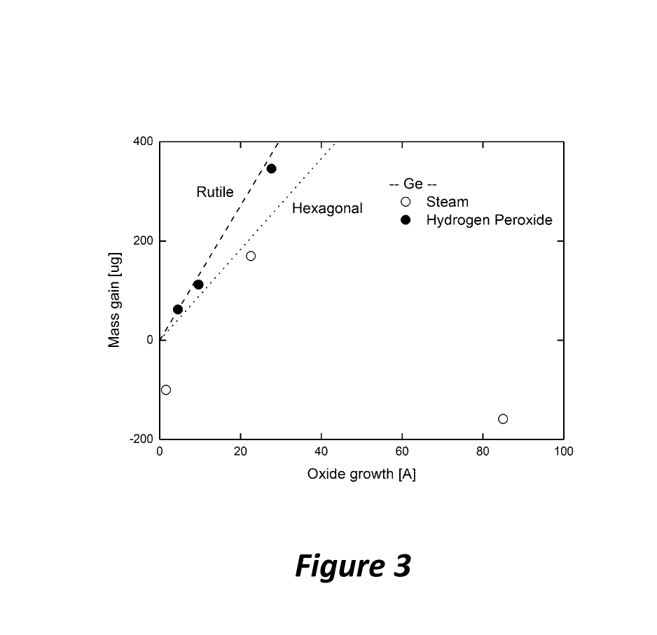

FIG. 3 shows a plot of the increase in mass of germanium substrates as a function of the increases in the thicknesses of the oxide layers formed by the oxidations of FIG. 2. The Y-axis shows in micrograms (ug) the increase in mass of the substrates and the X-axis shows in angstroms the increases in the thicknesses of the oxide layers formed by the oxidations. It will be appreciated that the rutile and hexagonal forms of germanium oxide have densities of about 6.27 g/cm³ and about 4.25 g/cm³, respectively. Consequently, different amounts of mass gain per unit of oxide growth would be expected depending on the form taken by the germanium oxide. As shown in FIG. 3, the data points for the hydrogen peroxide oxidation indicate that the dense oxide rutile form is produced by that oxidation, while the steam oxidation results indicate that the hexagonal form is produced by that oxidation. The steam oxidation results also show a loss of mass. This loss of mass is believed to be caused by steam etching away some of the germanium oxide. It will be appreciated that the wafers used contained an exposed germanium layer at one side of the substrate and germanium oxide was only formed at this side of the substrate. The other side of the substrate contained exposed silicon.

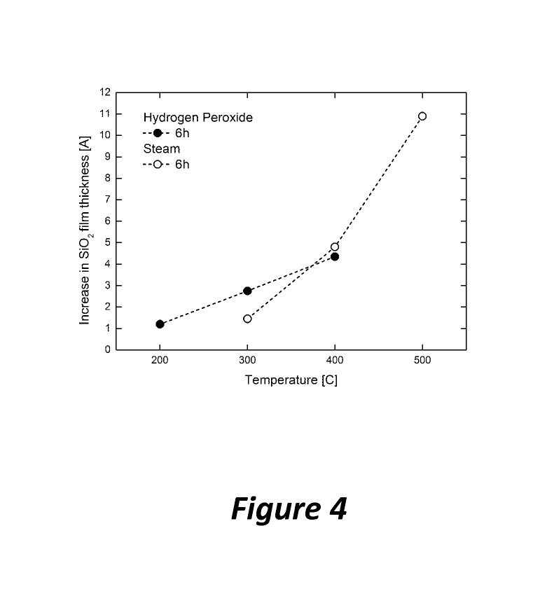

In addition to germanium-containing substrates, experiments were also performed on silicon substrates. FIG. 4 shows a plot of the increase in the thickness of oxide layers as a function of oxidation temperature for oxidations of monocrystalline silicon substrates in steam and hydrogen peroxide. The Y-axis shows in angstroms the increase in thickness of silicon oxide resulting from the oxidations and the X-axis shows in degrees Celsius the temperatures for the oxidations. Increases in oxide thickness with increasing temperature were observed for both steam and hydrogen peroxide. As with the oxidation of the germanium substrates, it was found that hydrogen peroxide produced useful oxide thicknesses even at a relatively low temperature of about 200° C., while steam required a temperature of about 300° C. to produce a similar oxide thickness.

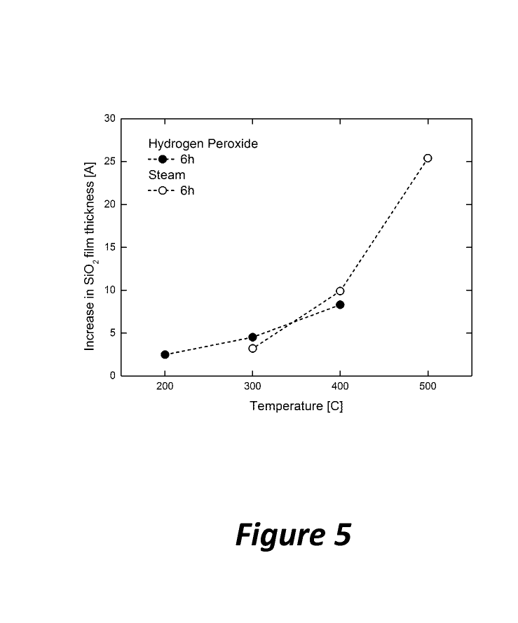

FIG. 5 shows a plot of the increase in the thickness of oxide layers as a function of oxidation temperature for oxidations of amorphous silicon substrates in steam and hydrogen peroxide. The Y-axis shows in angstroms the increase in thickness of silicon oxide resulting from the oxidations and the X-axis shows in degrees Celsius the temperatures for the oxidations. The oxide thickness increased with increasing temperature for both steam and hydrogen peroxide. As with the oxidation of the monocrystalline silicon substrates, hydrogen peroxide was found to be significantly more reactive than steam at temperatures under 300° C. (and particularly at lower temperatures such as 200° C.), while steam required a temperature of about 400° C. to reach a similar reactivity as hydrogen peroxide. In these figures, the reactivity of the oxidants was understood to correspond to the thickness of the oxide grown by the oxidation.

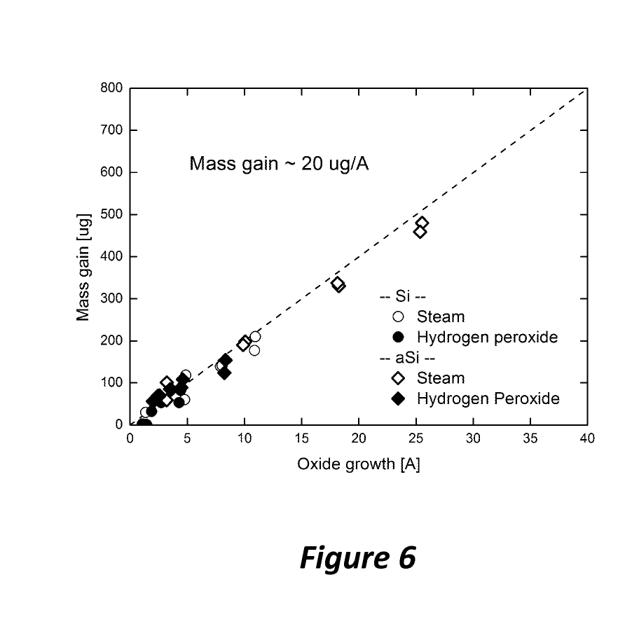

FIG. 6 shows a plot of the increase in mass of monocrystalline and amorphous silicon substrates as a function of the thicknesses of the oxide layers formed by the oxidations of FIGS. 4 and 5. The Y-axis shows in micrograms the increase in mass of the substrates and the X-axis shows in angstroms the increases in the thicknesses of the oxide layers formed by the oxidations. As shown, the mass increases for the steam and hydrogen peroxide oxidations of both the monocrystalline silicon and amorphous silicon (a-Si) substrates are similar, indicating that the densities of the oxides formed by both oxidants is similar. Thus, the quality of the silicon oxide formed by hydrogen peroxide is expected to be at least comparable to that formed by conventional steam processes. However, as seen in FIGS. 4 and 5, hydrogen peroxide provides significantly higher rates of growth.

It will be appreciated by those skilled in the art that various omissions, additions and modifications can be made to the processes and structures described above without departing from the scope of the invention. It is contemplated that various combinations or sub-combinations of the specific features and aspects of the embodiments may be made and still fall within the scope of the description. Various features and aspects of the disclosed embodiments can be combined with, or substituted for, one another in order. All such modifications and changes are intended to fall within the scope of the invention, as defined by the appended claims.

What is claimed is:

1. A method for semiconductor processing, comprising:
growing an oxide layer on a semiconductor substrate, the oxide layer growing by a thickness of about 1 Å or more, wherein growing the oxide layer comprises:
oxidizing the semiconductor substrate by exposing the semiconductor substrate to hydrogen peroxide at a process temperature of about 500° C. or less.

2. The method of claim 1, wherein growing the oxide layer comprises:
oxidizing a germanium-containing substrate,
wherein the oxide layer comprises germanium oxide.

3. The method of claim 2, wherein oxidizing the germanium-containing substrate comprises oxidizing a silicon-germanium substrate.

4. The method of claim 2, wherein oxidizing the germanium-containing substrate comprises oxidizing a germanium substrate.

5. The method of claim 2, wherein the germanium oxide has a density of about 6 g/cm³ or more.

6. The method of claim 5, wherein the germanium oxide is in a rutile form.

7. The method of claim 1, wherein oxidizing the substrate comprises oxidizing a silicon substrate.

8. The method of claim 1, wherein the substrate comprises a group III-V semiconductor.

9. The method of claim 1, wherein the process temperature is about 400° C. or less.

10. The method of claim 1, wherein oxidizing the semiconductor substrate further comprises exposing the semiconductor substrate to water vapor.

11. The method of claim 10, wherein exposing the semiconductor substrate to water vapor and exposing the semiconductor substrate to hydrogen peroxide are performed simultaneously.

12. The method of claim 1, wherein growing the oxide layer is accomplished by thermal oxidation.

13. A method for semiconductor processing, comprising:
forming an oxide layer by exposing a semiconductor substrate to hydrogen peroxide, wherein a process temperature for exposing the semiconductor substrate is about 500° C. or less while forming the oxide layer; and
depositing an other layer of material directly on the oxide layer.

14. The method of claim 13, wherein the process temperature is about 400° C. or less while forming the oxide layer.

15. The method of claim 14, wherein the process temperature is about 300° C. or less while forming the oxide layer.

16. The method of claim 13, wherein exposing the semiconductor substrate comprises exposing a germanium-containing substrate to the hydrogen peroxide.

17. The method of claim 13, wherein exposing the semiconductor substrate comprises increasing a density of oxide on a surface of the germanium-containing substrate.

18. The method of claim 17, wherein an oxide on a surface of the germanium-containing substrate has a density of about 5 g/cm³ or less before exposing, and a density of about 6 g/cm³ or more after exposing.

19. The method of claim 13, wherein exposing the semiconductor substrate comprises feeding an aqueous hydrogen peroxide solution to and evaporating in an evaporator heated to an evaporation temperature of 120° C. to 40° C.

20. The method of claim 13, wherein forming the oxide layer is performed without exposing the semiconductor substrate to radical species.

21. The method of claim 13, wherein depositing the other layer of material comprises depositing a dielectric layer.
